(19) United States
(12) Patent Application Publication
(10) Pub. No.: US 2025/0385195 A1
(43) Pub. Date: Dec. 18, 2025

(54) SEMICONDUCTOR DEVICE AND METHOD FOR MANUFACTURING

(71) Applicant: Infineon Technologies Austria AG, Villach (AT)

(72) Inventor: Zhe Zhang, Heidelberg (DE)

(21) Appl. No.: 19/228,159

(22) Filed: Jun. 4, 2025

(30) Foreign Application Priority Data
Jun. 18, 2024 (DE) 102024205603.0

(51) Int. Cl. H01L 23/538; H01L 23/60; H01L 23/66; H01L 25/00; H01L 25/16

(52) U.S. Cl. CPC H01L 23/5389; H01L 23/5383; H01L 23/5386; H01L 23/60; H01L 23/66; H01L 25/16; H01L 25/50; H01L 2223/6616; H01L 2223/6655

(57) ABSTRACT

A semiconductor device includes a substrate and a die embedded in the substrate. The substrate is a multilayer substrate including: an electrically conductive topside layer forming a topside of the semiconductor device; an electrically conductive bottom side layer forming a baseplate of the semiconductor device; a first electrical connector, between the topside layer and the bottom side layer; and a second electrical connector coupling the bottom side layer and/or the topside layer to a potential other than ground.

### TECHNICAL FIELD

The present disclosure relates to a semiconductor device and a corresponding manufacturing method.

### BACKGROUND

The invention relates to a semiconductor device, in particular a semiconductor device having a semiconductor chip embedded in an inside of the semiconductor device or inside a substrate comprised in the semiconductor device. Furthermore, the invention relates to a manufacturing method for producing the above-mentioned semiconductor device. In particular, the above-mentioned semiconductor device has a leadframe with a die pad on which the semiconductor chip is mounted. If appropriate, the semiconductor device, particularly the substrate, is connected to an external heat sink, which in turn consists of an electrically conductive material. Depending on the switching state of the semiconductor chip, charge shifts occur within the semiconductor device. However, since the leadframe and the heat sink must be separated from one another by an electrically insulating layer, capacitive couplings occur between the semiconductor chip and the heat sink depending on the switching state.

Generally, in a multilayer substrate or in a semiconductor device comprising multiple electrically conductive layers in a stack together with electrically isolating layers, stray capacitances occur, because the electrically conductive layers form capacitive structures together with the electrically isolating layers.

A current which is proportional to a capacitance C formed between the substrate and the heatsink, flows through the electrically conductive structures inside the semiconductor device during switching on and off of the semiconductor device, i.e. a die inside the semiconductor device. This current in turn generates magnetic fields which lead to stray inductances.

Stray inductances in turn influence control currents in the components to be switched. Overall, electromagnetic radiation triggered by interference capacitances and stray inductances thus occurs in the semiconductor device during switching on and off the semiconductor die, which electromagnetic radiation can in turn sensitively influence the mode of operation of the semiconductor device. Furthermore, electromagnetic oscillations can also act on an environment of the semiconductor device, which can lead to undesired interference effects, generally known as electromagnetic interference (EMI).

It is therefore an object of the present disclosure to at least mitigate these interference effects.

### SUMMARY

According to a first aspect of the disclosure a semiconductor device is provided comprising a substrate, and a die embedded in the substrate, wherein the substrate is a multilayer substrate comprising an electrically conductive topside layer forming a topside of the semiconductor device, an electrically conductive bottom side layer forming a baseplate of the semiconductor device, and a first electrical connector, between the topside layer and the bottom side layer; and a second electrical connector coupling the bottom side layer and/or the topside layer to a potential other than ground.

The electrically conductive topside layer and the electrically conductive bottom side layer may form two sites, namely a bottom side and topside and hence a housing of the semiconductor device. Additionally, the connector, which electrically couples the topside with the baseplate, may form a vertical connection between the topside layer and the bottom side layer. By electrically connecting the adjacent layers, undesired capacitive couplings between those layers are removed, or at least mitigated. In semiconductor devices of the aforementioned kind, a plurality of conductive layers, which are substantially parallel may be comprised in the semiconductor device. These layers are usually separated to one another by isolating materials. The isolating materials may be dielectric materials. In such arrangements undesired capacitors, namely neighboring electrically conductive layers separated by isolating dielectric layers are formed. During switching the semiconductor device on or off, i.e. during voltage changes due to the switching state, load carriers are accumulated within these capacitive structures formed by the conductive layers separated by dielectric materials. By electrically connecting adjacent electrically conductive layers a capacitive coupling between them can be at least mitigated.

For example, when attaching a metal heatsink to the bottom layer, a capacitive coupling between the switch and the heatsink is formulated. In the events of switching on/off, the common mode current is formed to parasitic capacitance and flows through the heatsink down to the ground point, causing further noise disturbance to the whole electrical system. In the present disclosure the first electrical connector decouples an electromagnetic field between a source of electromagnetic radiation and for example the heatsink. Further, current flows to ground, that is, a ground potential, are leakage currents and are hence to be regarded as being parasitic. Particularly in Silicon Carbide (SiC) and Gallium Nitride (GaN) applications, i.e. if a SiC/GaN die is used, flanks of the switching voltage are steep, causing high leakage currents towards ground. To mitigate such leakage currents, the second electrical connectors couple the bottom side layer and/or the topside layer to a potential other than ground, e.g. the minus potential of a power source as will be further detailed below.

As capacitive couplings between electrically conductive layers of a semiconductor device cause current flows during changing the switching state, these current flows along the conductive layers also course stray inductances, which in turn may cause current flows in other parts within the semiconductor device. By reducing the capacitive couplings between neighboring layers within a device, stray inductances and their adverse effects are also decreased. As a result, the electromagnetic radiation within the semiconductor device is lowered.

The semiconductor device of the present disclosure further comprises a substrate and a die embedded in the substrate, wherein the substrate is a multilayer substrate comprising the topside layer, the bottom side layer, and the first and second electrical connectors.

The semiconductor device may comprise the substrate or the substrate may be the semiconductor device. Alternatively, the semiconductor device may comprise several stacked conductive layers. The die may be embedded within or in between electrically conductive layers. The die may be embedded in a cavity of the substrate or may be packaged separately and may somehow be inserted into the substrate so that the die is located at least between the topside layer and the bottom side layer. Further, electrically conductive layers may be comprised in the substrate; however they may be sandwiched between the topside layer and the bottom side layer.

In an embodiment, the topside layer and the bottom side layer may form an electrically conductive housing of the semiconductor device. Those layers are connected by the first electrical connector such that a Faraday cage is formed around the die. Therefore, the die may be surrounded by more than one first connector, such that the die is encaged by the topside layer and the bottom side layer and the connector within the semiconductor device. By forming a Faraday cage around the die, electromagnetic radiation caused by the die is prevented from proliferating out of the cage. Hence, the overall electromagnetic interference caused by the semiconductor device is decreased.

In an embodiment, the first electrical connector is an integral part of the topside layer and the bottom side layer; and the first electrical connector is forming a vertical sidewall of the semiconductor device. Particularly, the first electrical connector may be a layer structure. The first electrical connector may be one integral part with the bottom layer and topside layer. The first electrical connector may hence form at least one side wall of the housing. A layer-structured first connector may also form more sidewalls of the housing and may also fully house the substrate and/or the die. The first connector may be a continued thin metal layer extended from the topside layer or bottom side layer to the respective opposite layer. Thereby the substrate and/or the die may be fully encased in an electrically conductive housing. A conductive layer including topside layer, the bottom side layer and the vertical layer structured connector enclose all or part of the die, which is the source of electromagnetic radiation to ensure the decoupling of the electromagnetic field from the die towards the external environment. The vertical layer/layer-structured first connector may be realized by the extension of the conductive bottom side layer to the conductive topside layer.

In an embodiment of the disclosure, the first electrical connector is a plurality of first vias, particularly an alley of first vias caging the die.

The first electrical connector may consist of a plurality of connectors, for example a plurality of pillars, vias or the like. The vertical layer may also be realized by vertical via arrays. Particularly, the Faraday cage around the die is formed by an alley of vias or by an alley of pillars, which form first electrical connectors between the top and the bottom layer.

In an embodiment of the disclosure, the bottom side layer of the multilayer substrate is configured to be attached to a heatsink. As the bottom layer is electrically conductive and hence thermally conductive, a suitable material may be chosen to adapt the bottom side layer to be coupled to a heatsink. Thereby, the heatsink and the electrically conductive bottom side layer may be at the same potential forming at least one part of a capacitive structure. As in this case the first electrical connector between the bottom side layer, and hence the heatsink, will shortcut the capacitive structure formed by the heatsink and the possibly adjacent conductive layer, which is separated from the bottom side layer by a dielectric. As the heatsink is usually on a ground potential, the leakage current will flow to ground during switching. The second electrical connectors connect the capacitive structure, however, to a potential lower than ground to re-direct the current flow away from ground.

In an embodiment, the second electrical connector is a plurality of second vias.

In an embodiment of the semiconductor device a distance between neighboring first and/or second vias is below a wavelength of the electromagnetic radiation emitted by the die during switching inside the Faraday cage of the semiconductor device. By the plurality of stray inductances and capacitive effects within the semiconductor device, electromagnetic noise is generated within the semiconductor device. This noise may have an average wavelength corresponding to a frequency in a range of about 1 GHZ. By choosing a distance of first and/or second connectors/vias below the average wavelength of the electromagnetic radiation inside the Faraday cage of the semiconductor device, at least part of the radiation is prevented from leaving the Faraday cage. A shielding effect of the electrical connectors may thereby be enhanced.

In an embodiment of the present disclosure, the device comprises a DC link, the DC link comprising a first DC connector, a second DC connector; and an output connector, wherein the topside layer and/or the bottom side layer comprises openings to expose the first DC connector, the second DC connector and the output connector. The DC link may be a connection to an external control source like a microcontroller or a gate driver, controlling the switching signals of the die inside the substrate of the semiconductor device. Moreover, the output connector may be the connector for the output signal generated by the die in response to the input signal.

In an embodiment the semiconductor device comprises a capacitor arrangement which is part of the DC link and configured for high frequency filtering, wherein the capacitor arrangement is coupled between the first DC connector and the second DC connector. The capacitor arrangement may consist of at least two DC link capacitors coupled between the first DC connector and the second DC connector. A capacitance of the capacitor arrangement may be such that high frequency filtering of the input signal is enabled.

In an embodiment the semiconductor device comprises a further electrically conductive layer between the topside layer and the bottom side layer, the further electrically conductive layer being separated from the topside or bottom side layer by a dielectric.

In an embodiment of the disclosure the bottom side layer or the topside layer is electrically coupled to a mid-point of the capacitor arrangement or to a minus point of the DC link, particularly by the further electrically conductive layers and/or the second vias.

In an embodiment the mid-point is a point between capacitors of the capacitor arrangement, and wherein the capacitor arrangement comprises at least two capacitors connected to one another in series, and wherein both the mid-point and the DC minus point of the DC link are at a potential lower than ground. The midpoint of the DC link may be connected to either the bottom layer or topside layer through the second vias (second electrical connectors) or any other type of electrical connectors. By connecting, for example, the bottom side layer to the midpoint of the DC link or alternatively to a minus potential of the DC link, electromagnetic noise caused by the die inside the Faraday cage can be returned back to the power tank. As the mid-point potential and particularly the DC minus potential are lower than ground, the capacitive leakage currents will not flow to ground but recycle into the DC link. The DC link may be integrated into lamination layers of the substrate or may be located on top of a lamination layer. The DC link may be placed inside the substrate to achieve a small current commutation and to absorb electromagnetic noise from a switching stage. This enables recycling of electromagnetic noise into the DC link, but not floating it.

In a further embodiment, the semiconductor device comprises a low pass filter for smoothing an output signal output via the output connector, the low pass filter being embedded in the substrate and located inside the Faraday cage.

The lowpass filter may be an integrated output filter which is adapted for smoothing the output high frequency signal. As on the output side of the die high voltage changes occur during switching, the output connector would become an antenna. This is prevented by filtering the output signal by the low pass filter. The lowpass filter helps to smoothen the high frequency output signal and subsequently reduces electromagnetic radiation caused by the output connector.

In an embodiment the semiconductor device comprises a plurality of dies, wherein the plurality of dies forms a half-bridge arrangement.

In an embodiment, the low pass filter comprises at least one of: an LC arrangement comprising an inductance L and a capacitor C, an LCL arrangement comprising two inductances and a capacitor, a capacitor. The low pass filter is electrically coupled between: the mid-point of the half-bridge; and the baseplate or the topside layer.

Particularly, the inductance L is coupled to the mid-point of the half-bridge and/or the capacitor C is coupled to the baseplate which is in turn coupled to the mid-point of the DC-link via the second electrical connectors. As an example, electromagnetic noise inside the Faraday cage above 10 MHz can be smoothened with a capacitor of 1 μF and an inductor of 0.1 μH. Again, the midpoint of the DC link is connected to the integrated output filter and a midpoint layer may be beneath the external layer. The capacitor is coupled to ground and/or the baseplate. To avoid the baseplate from being flooded by load carriers, the baseplate is electrically coupled, by the second electrical connectors, to a lower potential, which is either midpoint DC link or the DC minus potential.

In a further embodiment, the DC connectors and the output connector comprise third vias which are routed through the openings in the topside layer to an outside of the semiconductor device and wherein the third vias are electrically isolated towards the topside layer. In this embodiment, the DC link and the output connectors are arranged inside the housing. The DC link and output connectors are led to the outside of semiconductor device by third via this, wherein the third vias are routed through the openings in the topside layer. The third vias are electrically isolated from the topside layer. A diameter of the vias is less than the diameter of the openings. The third vias may be connected to DC terminals above the topside layer and the outside of the Faraday cage of the semiconductor device.

In a further embodiment a diameter of the openings is less than half of the wavelength of the electromagnetic radiation inside the Faraday cage of the semiconductor device. This contributes to full encapsulation of the die inside the Faraday cage.

In an embodiment the die is one of a GaN HEMT, a SiC MOSFET, a Si IGBT, a Si MOSFET.

According to a second aspect of the present disclosure a method for manufacturing a low EMI semiconductor device is provided, the method comprising: providing a substrate, embedding a die in the substrate; forming a topside of the semiconductor device by providing an electrically conductive topside layer at the substrate; forming a baseplate of the semiconductor device by providing an electrically conductive bottom side layer substantially parallel to the topside layer at the substrate; forming an electrical connector between the topside layer and the bottom side layer; forming a second electrical connector; and coupling, by the second electrical connector, the bottom side layer and/or the topside layer to a potential other than ground.

All of the embodiments disclosed and described in relation to the first aspect of the disclosure can also be conceived in connection with the second aspect of disclosure.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 shows a schematic illustration of an aspect of the present disclosure.

FIG. 2 is an illustrative 3-D view of an exemplary embodiment of the present disclosure.

FIG. 3 is a topside 3D view of the embodiment of FIG. 2.

FIG. 4 is a schematic side view of the embodiment of FIG. 2 and FIG. 3.

FIG. 5 is a transparent view of the embodiment of FIG. 4.

FIG. 6 is the detailed perspective view of the capacitor arrangement of the DC link.

FIG. 7 is a circuit diagram of the lowpass filter according to the disclosure.

FIG. 7a is a further schematic illustration of the disclosure.

FIG. 8 is a schematic illustration of the third vias.

FIG. 9 is a flow diagram according to a second aspect of disclosure.

### DETAILED DESCRIPTION

In the following, various embodiments of the disclosure are described by the examples.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

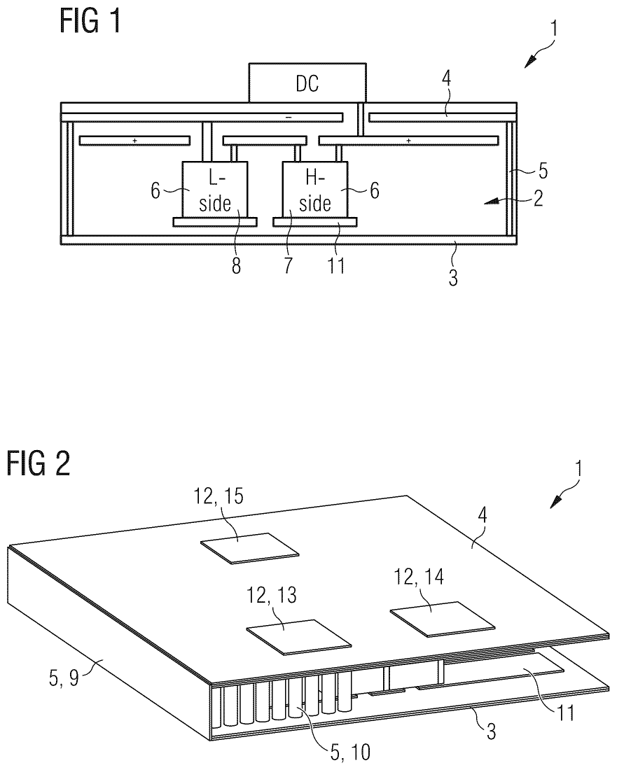

FIG. 1 shows a schematic illustration of a semiconductor device 1. The semiconductor device 1 may comprise or may consist of a substrate 2. The substrate 2 may be a multilayer substrate 2, comprising multiple conductive layers, separated by isolating dielectric layers. The semiconductor device 1 comprises an electrically conductive bottom side layer 3, which may be the baseplate, and which can be configured to be attached to a heatsink (not shown). The semiconductor device 1 further comprises an electrically conductive topside layer 4, or uppermost layer. An electrical connector 5 is formed between the electrically conductive bottom side layer 3 and the electrically conductive topside layer 4, thereby electrically connecting both layers. The electrical connector 5 may also be part of the substrate 2. The topside layer 4, the bottom side layer 3 and the electrical connector 5 form a Faraday cage around a die 6, which can also be referred to as a semiconductor arrangement 6, inside the semiconductor device 1.

The semiconductor arrangement 6 may be a semiconductor die 6 and comprises a high side switching arrangement 7 and a low side switching arrangement 8. The semiconductor device 1 further comprises an energy source, which may be a direct current source. The direct current source (DC link) feeds the semiconductor arrangement 6. The topside layer 4, which is electrically connected to the bottom side layer 3, by the electrical connector 5, is coupled to a minus potential of the DC power source, to decouple an electrical field induced between the topside layer 4 and the bottom side layer 3 by switching activities of the semiconductor arrangement 6. By coupling the topside layer 4 to minus potential of the DC power source the topside layer 4 is prevented from being flooded by load carriers.

FIG. 2 is an illustrative 3-D view of an exemplary embodiment of the present disclosure. The topside layer 4 and the bottom side layer 3 are substantially parallel. The electrical connector 5 forms or is formed by a vertical side wall 9. The electrical connector 5 may also be formed by an array of pillars or first vias 10. The electrical connector 5 forming the side wall 9 may be an integral part of the topside layer 4 and the bottom side layer 3. For example, the connector 5 may be formed by bending a single metal sheet to form the bottom side layer 3, the topside layer 4 and the electrical connector 5 out of one single workpiece. Alternatively, or additionally, the semiconductor arrangement 6 can be encased by the first vias 10. The first vias 10 form an ally around the semiconductor arrangement 6.

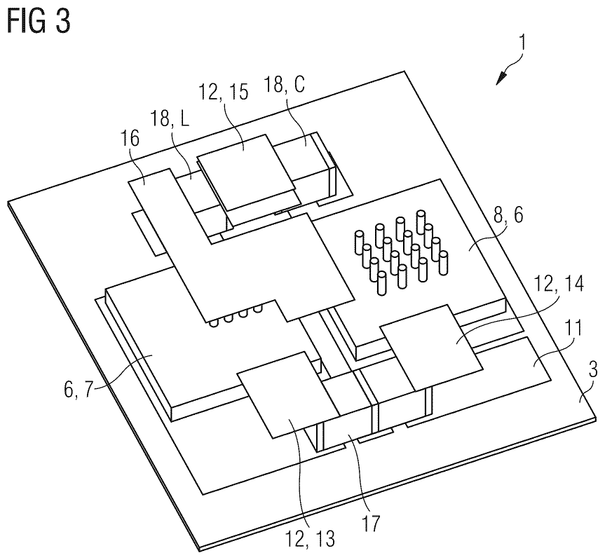

FIG. 3 is a topside 3-D view of the embodiment of FIG. 2. In the present view, the topside layer 4 and the vertical side wall 5, 9 are removed. The bottom side layer 3 forms the base plate 3 of the semiconductor device 1. The semiconductor device 1 comprises additional layers 11, which form electrical connectors between components of the semiconductor device 1. The additional layers 11 may be part of a leadframe, comprising die pads for accommodating the semiconductor arrangement 6. The high side switches 7 are arranged at the additional layers 11 inside the semiconductor device 1. The low side switches 8 are arranged inside the semiconductor device 1 at the additional layers 11 and adjacent to the high side switches 7. The semiconductor device 1 comprises contact pads 12, to connect the elements housed in the Faraday cage between topside layer 4 and the bottom side layer 3 to the outside world. The contact pads 12 are arranged substantially parallel above the topside layer 4 and are electrically isolated with respect to the topside layer 4.

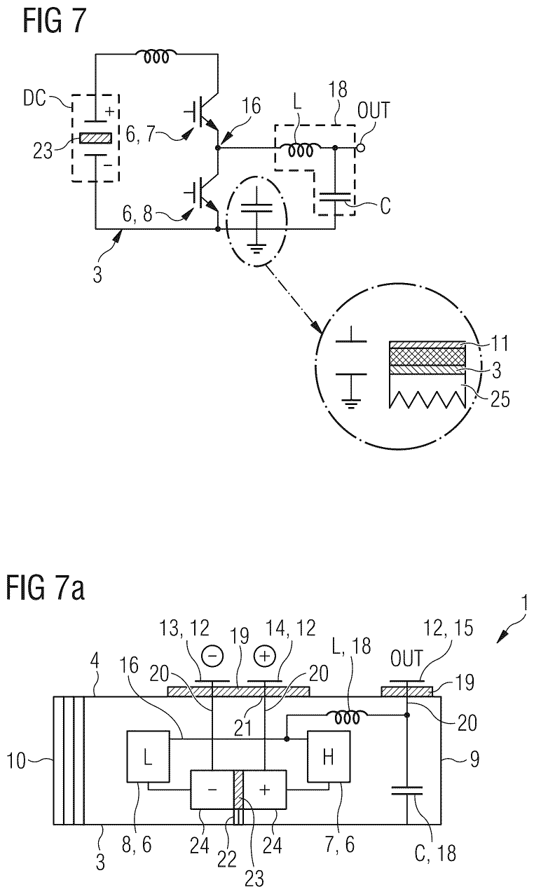

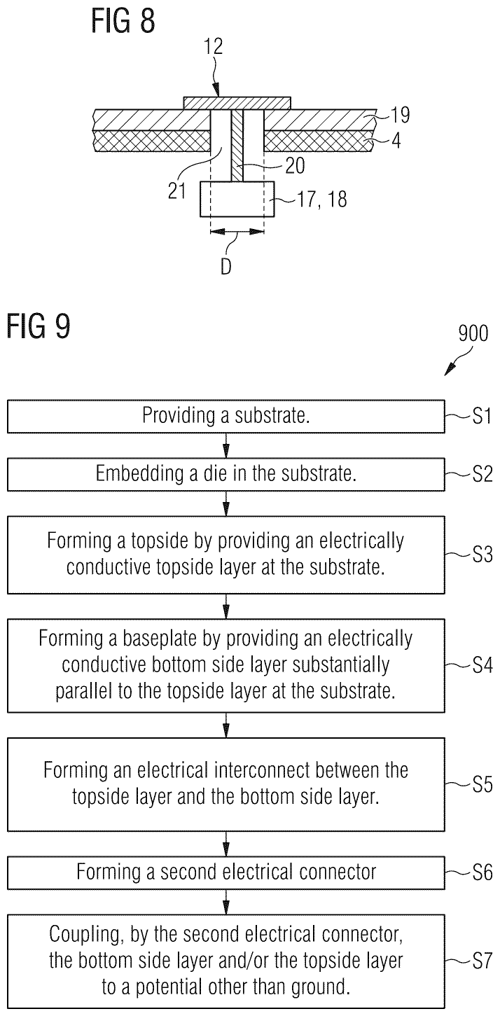

To contact the contact pads 12 from the inside of the semiconductor device 1, the topside layer 4 comprises openings 21 (not visible, see FIG. 7a and FIG. 8) through which the electrical contact pads 12 are contacted.

The contact pads 12 comprise a DC− connector 13, a DC+ connector 14 and an output connector 15. Further, the semiconductor device 1 comprises a midpoint connector 16 connecting the high side switches 7 and the low side switches 8. The midpoint connector 16 is layer-shaped. A capacitor arrangement 17 is arranged inside the semiconductor device 1 and connected to the DC minus connector 13 and the DC plus connector 14. The capacitor arrangement 17 is part of the DC power source. The capacitor arrangement 17 is configured for high frequency filtering. The capacitor arrangement 17 is electrically coupled between the first DC connector and the second DC connector, i.e. the DC− connector 13 and the DC+ connector 14.

The semiconductor device 1 further comprises a lowpass filter 18. The lowpass filter 18 comprises an inductor L and a capacitive filter C. The contact pad 12 of the output connector 15 is arranged atop the lowpass filter 18 and electrically connected to the lowpass filter 18, as will be detailed below.

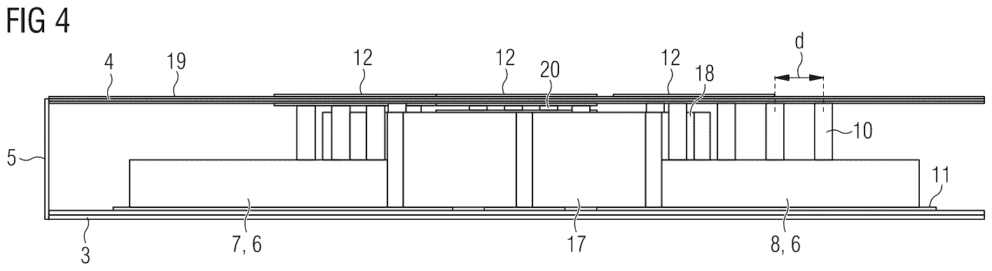

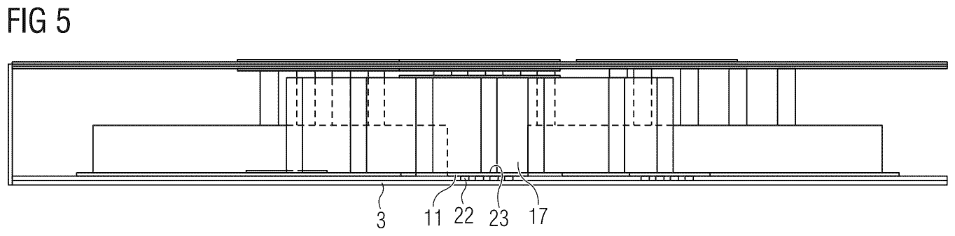

FIG. 4 is a schematic side view of the embodiment of FIG. 2 and FIG. 3. The topside layer 4 and the bottom side layer 3 are connected by vertical side wall 5. The topside layer 4 is covered by a further electrically isolating layer 19, isolating the contact pads 12 towards the topside layer 4. High side switches 7 and low side switches 8 are arranged inside the semiconductor device 1 and symmetrical with respect to the capacitor arrangement 17. The switches 7, 8 and the filters 17, 18 are sandwiched between the topside layer 4 and the bottom side layer 3 and further caged by the electrical connector 5 being formed as a vertical side wall 5 and an alley of first vias 10. The contact pads 12 of the DC power source, are contacted by third vias 20 through the openings 21 (not visible) in the topside layer 4. A distance d between the first vias 10 is below a wavelength of the electromagnetic radiation produced by the semiconductor die 6 inside the Faraday cage of the semiconductor device 1.

FIG. 5 is a transparent view of the embodiment of FIG. 4. In this view, second vias 22 become visible, the second vias 22 connecting the baseplate 3 to a midpoint 23 of the capacitor arrangement 17 of the DC link. The second vias 22 may also connect the baseplate 3 and an additional layer 11, which is electrically conductive, to the DC link. The Faraday cage, formed by the electrically conductive topside and a bottom side layers, is thereby connected to a lower potential. The Faraday cage can either be connected to a midpoint of the capacitor arrangement 17 or to a minus potential of the DC link to avoid any of the layers being flooded by load carriers, caused by a capacitive coupling between the two layers. Thereby, load carriers can be recycled into the power source.

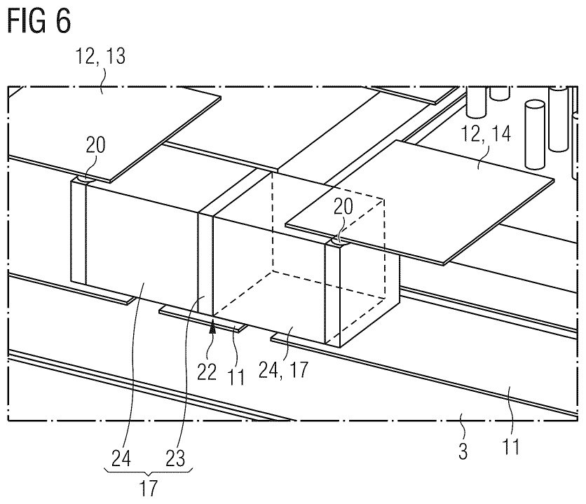

FIG. 6 is a detailed 3-D view of the capacitor arrangement 17 of the DC link. The capacitor arrangement 17 comprises at least two capacitors 24 coupled to one another in series. The area between the capacitors 24 is the midpoint of the DC link 23. The midpoint of the DC link 23 is coupled to additional layer 11 by the second vias 22 (not visible) from below. The capacitors 24 are connected to the contact pads 12 by the third vias 20. Thereby, the capacitor arrangement 17 is coupled between the first DC connector 13 and the second DC connector 14, to enable high frequency filtering.

FIG. 7 is a circuit diagram showing the lowpass filter 18. The lowpass filter 18 is configured for smoothing an output signal which is output from the semiconductor arrangement 6 towards the output connector 15. The lowpass filter 18 can be embedded in the substrate and/or housed inside the Faraday cage of the semiconductor device 1. For smoothing the output signal, this lowpass filter 18 may consist of an inductance L together with a capacitor C. Alternatively, the lowpass filter 18 may consist of an inductance L followed by the capacitor C, followed by an inductance L. Alternatively, a single capacitor C may be used for filtering.

The lowpass filter 18 is electrically coupled between the midpoint connector 16, which is an electrical connection to a midpoint between the high side switches 7 and the low side switches 8 of a half bridge and the baseplate 3. As the baseplate 3 is electrically coupled to a lower potential, i.e. midpoint 23 of the DC link or the minus potential of the DC link, an undesired coupling of the lowpass filter 18 to ground (which is the case if a heatsink 25 is connected to the baseplate 3, see expansion at FIG. 7) is removed or at least mitigated. In the present embodiment shown in FIG. 7, an inductance L of the lowpass filter 18 is coupled to the midpoint 16 between the low side and the high side, and the capacitor C is coupled to the baseplate 3.

FIG. 7 shows a capacitor connected to ground, which is explained in more detail in the expansion view. The depicted capacitor is for explanatory purposes only and is not part of the embodiment.

As can be seen in the expansion of FIG. 7, in case of a heatsink 25 being attached to the baseplate 3, a capacitance is formed between one of the additional layers 11 and the baseplate 3/heatsink 25. As the heatsink 25 is usually made of metal, it constitutes a reservoir for load carriers, moved by the capacitive coupling between the two layers 3, 11. However, in this case the load carriers will tend to flow to the lowest available potential, which is ground. Current flow to ground is, however, not desired. This undesired current flow can be at least mitigated by connecting the lowpass filter, particularly the capacitor of the lowpass filter 18, to midpoint DC link 23, e.g. by connecting it to the housing. Load carriers being moved by the output signal (OUT) within the lowpass filter 18 can hence be redirected into the DC power source and hence be recycled.

FIG. 7a shows a schematic overview of the semiconductor device 1. FIG. 7a shows the switching arrangement 6, comprising high side switches H, 7 and low side switches L, 8 being encased in the semiconductor device 1. Together with the switching arrangement, the DC link arrangement comprising two capacitors 24 is encased inside the semiconductor device 1. The inside of the semiconductor device 1 is encased by the baseplate 3 which is connected to the topside layer 4 by the first vias 10. The first vias 10 may form an alley or a row, or may be embodied as a row of pillars, or vertical side walls 9. The DC link arrangement is configured for high frequency filtering. A lowpass filter 18 consisting of an inductance L and a capacitor C is also encased in the semiconductor device 1. An output terminal (output connector 15) is connected in between the inductance L and the capacitor C. The lowpass filter 18 is connected between the midpoint of the half bridge 16 and the baseplate 3, wherein the capacitor C is coupled to the baseplate 3. The baseplate 3 is electrically coupled to a topside layer 4 by the first vias 10 and/or the vertical side wall 9. Thereby the capacitor C of the output filter 18 is electrically coupled to both the baseplate 3 and the topside layer 4. In the embodiment shown in FIG. 7a the baseplate 3 is connected by second vias 22 to the midpoint of the DC link arrangement 23. Thereby, load being moved by capacitive effects between topside layer 4 and the baseplate 3 and/or by capacitive loads of the capacitor C of the lowpass filter 18, are fed back to the lower potential of the midpoint of DC link 23. Alternatively, load carriers maybe fed back to the lower potential of the minus side of the DC link 23, by the second vias 22.

The topside layer 4 comprises openings 21 (not visible). Contact pads 12 forming DC connectors 13, 14 are disposed above the topside layer 4, and may be electrically isolated and spaced apart from the topside layer 4 by isolating layer 19. DC connectors 13, 14 are connected to the DC link arrangement by third vias 20. Likewise output connector 15 is arranged on a top side of the semiconductor device 1 and spaced apart and electrically isolated with respect to the topside layer 4, by isolating layer 19. Both the contact pads of the DC connectors 13, 14 and the output connector 15 are contacted, that is electrically connected to an inside of the semiconductor device 1 by the third vias 20. The output connector 15 is electrically coupled, by third vias 20, to a point between the inductance L and the capacitor C of the lowpass filter 18.

The third vias 20 are routed from inside the semiconductor device 1 through the openings 21 to establish electric contact with the contact pads 12. The third vias 20 are electrically isolated towards the bottom side layer 3 and or the topside layer 4. The third vias 20 are electrically isolated towards all of the elements of the semiconductor device 1, which form the Faraday cage and which hence encage the inside elements of the semiconductor device 1.

FIG. 8 is a schematic illustration of the third vias 20. The third vias 20 are electrical connectors connecting the capacitor arrangement of DC link 17 and/or the lowpass filter 18 through the openings 21 normal to the contact pads 12 outside the topside layer 4. Input signals received from an upstream source (not shown) being received by the contact pads 12 are routed by the third vias 20 through the opening 21 to the capacitor arrangement 17 of DC link. A diameter D of the openings 21 is less than half of the wavelength of the electromagnetic radiation inside the semiconductor device 1. Thereby electromagnetic radiation produced by the switching of the die arrangement inside the semiconductor device 1 is prevented from leaving the Faraday cage.

The contact pads 12 are isolated towards the topside layer 4 by isolating layer 19, to avoid inadvertent short-circuiting. The isolating layer 19 may cover the openings 21 (not shown). The isolating layer 19 may also contact the third vias 20, to fully surround them, and to fully cover a portion of the third vias 20, namely the portion between the topside layer 4 and the contact pad 12. The capacitor arrangement 17 may be electrically coupled to the contact pad 12 by a plurality of third vias, each third via of the plurality of third vias being routed to a respective plurality of openings 21.

FIG. 9 is a flow diagram of a method 900 for manufacturing a low EMI semiconductor device 1 according to the present disclosure.

In a first step S1, the substrate 2 is provided. The substrate 2 may be a layered substrate 2 but may also be any other kind of stacked electrical arrangement as shown and described in relation to the foregoing figures.

In a second step S2, a die 6 in is embedded in the substrate 2. That means the die 6 is arranged in an inside space of the substrate 2 or the stacked electrical arrangement.

In a third step S3, an electrically conductive topside layer 4 is provided on top of the substrate 2.

In a further step S4, a baseplate 3 consisting of a second electrically conductive layer is provided at the bottom side of the substrate 2. The baseplate 3 being the conductive bottom side layer is substantially parallel to the topside layer 4.

Finally, in step S5, an electrical connector is formed between topside layer 4 and the bottom side layer 3, to electrically connect both layers 3,4.

In step S6, a second electrical connector is formed.

In step S7 the bottom side layer and/or the topside layer are coupled to a potential other than ground by the second electrical connector.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

### LIST OF REFERENCE SIGNS

1 semiconductor device
2 substrate
3 bottom side layer/baseplate
4 topside layer
5 electrical connector
6 die/semiconductor arrangement
7 high side switches
8 low side switches
9 vertical side wall
10 first vias
11 additional layer
12 contact pads
13 DC− connector
14 DC+ connector
15 output connector
16 midpoint connector/midpoint half bridge
17 capacitor arrangement
18 lowpass filter
19 electrically isolating layer
20 third vias
21 openings
22 second vias
23 midpoint DC link
24 capacitors of capacitor arrangement
25 heatsink
900 Method

What is claimed is:

1. A semiconductor device, comprising:
a substrate; and
a die embedded in the substrate,
wherein the substrate is a multilayer substrate comprising:
an electrically conductive topside layer forming a topside of the semiconductor device;
an electrically conductive bottom side layer forming a baseplate of the semiconductor device;
a first electrical connector between the topside layer and the bottom side layer; and
a second electrical connector coupling the bottom side layer and/or the topside layer to a potential other than ground.

2. The semiconductor device of claim 1, wherein the topside layer, the bottom side layer and the first electrical connector form a Faraday cage around the die.

3. The semiconductor device of claim 2, wherein the first electrical connector is an integral part of the topside layer and the bottom side layer, and/or wherein the first electrical connector forms a vertical sidewall of the semiconductor device.

4. The semiconductor device of claim 1, wherein the first electrical connector comprises a plurality of first vias caging the die.

5. The semiconductor device of claim 1, wherein the bottom side layer is configured to be attached to a heatsink.

6. The semiconductor device of claim 1, wherein the second electrical connector comprises a plurality of second vias.

7. The semiconductor device of claim 6, wherein a distance between neighboring ones of the first vias is below a wavelength of the electromagnetic radiation emitted by the die during switching inside the Faraday cage.

8. The semiconductor device of claim 1, further comprising:
a DC link comprising a first DC connector and a second DC connector; and
an output connector,
wherein the topside layer and/or the bottom side layer comprises a plurality of openings to expose the first DC connector, the second DC connector and the output connector.

9. The semiconductor device of claim 8, wherein the DC link further comprises a capacitor arrangement configured for high frequency filtering, and wherein the capacitor arrangement is coupled between the first DC connector and the second DC connector.

10. The semiconductor device of claim 9, wherein the bottom side layer or the topside layer is electrically coupled to a mid-point of the capacitor arrangement or to a minus point of the DC link.

11. The semiconductor device of claim 10, wherein the mid-point is a point between capacitors of the capacitor arrangement, and wherein the capacitor arrangement comprises at least two capacitors connected to one another in series, and wherein both the mid-point and the DC minus point of the DC link are at a potential lower than ground.

12. The semiconductor device of claim 8, further comprising:
a low pass filter configured to smooth an output signal output via the output connector, the low pass filter being embedded in the substrate and located inside the Faraday cage.

13. The semiconductor device of claim 8, wherein the first DC connector, the second DC connector and the output connector comprise third vias which are routed through the openings in the topside layer to an outside of the semiconductor device, and wherein the third vias are electrically isolated towards the topside layer.

14. The semiconductor device of claim 13, wherein a diameter of the openings is less than half of the wavelength of the electromagnetic radiation inside the Faraday cage of the semiconductor device.

15. The semiconductor device of claim 1, further comprising:
a further electrically conductive layer between the topside layer and the bottom side layer, the further electrically conductive layer being separated from the topside layer or the bottom side layer by a dielectric.

16. The semiconductor device of claim 1, wherein the semiconductor device comprises a plurality of dies forming a half-bridge arrangement.

17. The semiconductor device of claim 16, further comprising:
a low pass filter configured to smooth an output signal output via the output connector, the low pass filter being embedded in the substrate and located inside the Faraday cage,
wherein the low pass filter comprises at least one of:
an LC arrangement comprising an inductance L and a capacitor C,
an LCL arrangement comprising two inductances and a capacitor,
a capacitor;
wherein the low pass filter is electrically coupled between:
the mid-point of the half bridge; and
the baseplate or the topside layer.

18. The semiconductor device of claim 17, wherein the inductance L is coupled to the mid-point of the half bridge and/or wherein the capacitor C is coupled to the baseplate.

19. The semiconductor device of claim 1, wherein the die is one of a GaN HEMT, a SiC MOSFET, a Si IGBT, and a Si MOSFET.

20. A method for manufacturing a low EMI semiconductor device, the method comprising:
providing a substrate;
embedding a die in the substrate;
forming a topside of the semiconductor device by providing an electrically conductive topside layer at the substrate;
forming a baseplate of the semiconductor device by providing an electrically conductive bottom side layer substantially parallel to the topside layer at the substrate;
forming a first electrical connector between the topside layer and the bottom side layer;
forming a second electrical connector; and
coupling, by the second electrical connector, the bottom side layer and/or the topside layer to a potential other than ground.
